(19) United States
(12) Patent Application Publication
(10) Pub. No.: US 2010/0019390 A1
(43) Pub. Date: Jan. 28, 2010

(54) SEMICONDUCTOR DEVICE, SEMICONDUCTOR CHIP, MANUFACTURING METHODS THEREOF, AND STACK PACKAGE

(76) Inventor: Oh-Jin Jung, Bucheon-si (KR)

Correspondence Address: SHERR & VAUGHN, PLLC, 620 HERNDON PARKWAY, SUITE 320, HERNDON, VA, 20170, US

(21) Appl. No.: 12/506,720

(22) Filed: Jul. 21, 2009

(30) Foreign Application Priority Data
Jul. 24, 2008 (KR) 10-2008-0072189
Dec. 23, 2008 (KR) 10-2008-0132099

(51) Int. Cl. H01L 23/48; H01L 21/768; H01L 21/22

(52) U.S. Cl. 257/774; 438/653; 438/510; 257/777; 257/E23.011; 257/E21.584; 257/E21.135

(57) ABSTRACT

A manufacturing method includes sequentially forming first and second material layers having different etch selectivities in a laminated fashion, patterning the second material layer, to form an etch mask, etching the first material layer using the etch mask, to form a via hole in the first material layer, forming a photo mask over the etch mask such that a region larger than the via hole is exposed through the photo mask, etching the etch mask using the photo mask, removing the photo mask, and forming a metal material over the first material layer, to fill the via hole. Accordingly, it is possible to prevent formation of a side wall undercut in a deep via etching process, and thus to ease subsequent processes for forming an oxide barrier film, a barrier metal film, and a metal layer.

The present application claims priority under 35 U.S.C. 119 to Korean Patent Application Nos. 10-2008-0072189 & 10-2008-0132099, (filed on 24 Jul. 2008 & 23 Dec. 2008, respectively), which are hereby incorporated by reference in their entirety.

### BACKGROUND

Current electronic product markets are rapidly expanding to portable products. Elements mounted in portable electronic products must be light, thin, simple, and miniature. For the sake of lightness, thinness, simplicity, and miniaturization of the elements, techniques for reducing individual sizes of elements to be mounted, such as semiconductor chips, must be used. These include system-on-chip (SOC) techniques for integrating a plurality of individual semiconductor chips into one chip, system-in-package (SIP) techniques for integrating a plurality of individual semiconductor chips into one package, etc.

To integrate a plurality of individual semiconductor chips into one package, the physical strength of the package should be enhanced. The performance and reliability of the chips mounted in the package should also be enhanced.

Hereinafter, a method for manufacturing a related semiconductor device will be described with reference to the accompanying drawings. FIGS. 1A to 1E are cross sectional views illustrating processes of a method for manufacturing a related semiconductor device. FIG. 2 shows a cross-sectional image of a semiconductor device shown in FIG. 1E.

As shown in FIG. 1A, over a silicon layer 1, an oxide film 2 is formed. The oxide film 2 is patterned to form an etch mask 2A. The etch mask 2A exposes a region 4 where a via hole will be formed, as shown in FIG. 1B. Using the etch mask 2A, the silicon layer 1 is etched to form a via hole 6 in the silicon layer 1A, as shown in FIG. 1C. Thereafter, a metal material 9 is filled in the via hole 6, as shown in FIG. 1D. The metal material 9 is then planarized to form a metal layer 9A, as shown in FIG. 1E.

In accordance with the above-mentioned related manufacturing method for a semiconductor device, undercuts 8A and 8B may be formed at an interface between the silicon layer 1A and the etch mask 2A. The undercuts 8A and 8B may degrade gap-fill characteristics in a subsequent metallization process, causing formation of voids in sidewalls. Another problem is that it may be impossible to form a conductive line.

### SUMMARY

Embodiments relate to a semiconductor device, a semiconductor chip, manufacturing methods thereof, and a stack package, and more particularly, to a semiconductor device having a via hole, a semiconductor chip having the semiconductor device, methods for manufacturing the semiconductor device and semiconductor chip, and a stack package using the semiconductor chip. Embodiments relate to a semiconductor device and a method for manufacturing the same, which are capable of preventing generation of an undercut upon forming a metal layer.

Embodiments relate to a semiconductor chip stack package capable of being designed irrespective of positions of semiconductor devices, lines, and contact plugs, and a semiconductor chip and a method for manufacturing the same, in which manufacture of a system-in-package (SIP) wafer can be achieved without formation of a contact plug (deep via) having a high aspect ratio.

Embodiments relate to a method for manufacturing a semiconductor device which includes sequentially forming first and second material layers having different etch selectivities in a laminated fashion, patterning the second material layer, to form an etch mask, etching the first material layer using the etch mask, to form a via hole in the first material layer, forming a photo mask over the etch mask such that a region larger than the via hole is exposed through the photo mask, etching the etch mask using the photo mask, removing the photo mask, and forming a metal material over the first material layer, to fill the via hole.

Embodiments relate to a semiconductor device which includes a via hole formed in a first material layer, an etch mask formed over the first material layer in accordance with patterning of a second material layer having an etch selectivity different from an etch selectivity of the first material layer, the etch mask exposing a region larger than the via hole, and a metal layer formed over the first material layer such that the metal layer fills the via hole.

Embodiments relate to a semiconductor chip which includes a wafer doped with impurity ions, a semiconductor device formed on the wafer, a metal electrically connected to the semiconductor device, a contact plug extending through an insulating layer formed on the wafer such that the contact plug is partially positioned within the wafer, and a line layer formed at one end of the contact plug, and electrically connected to the contact plug and the metal.

Embodiments relate to a method for manufacturing a semiconductor chip which includes doping impurity ions in a wafer to a predetermined depth, forming, on the wafer, a semiconductor device, an insulating layer to cover the semiconductor device, and a metal to be electrically connected to the semiconductor device, forming a passivation film to cover the metal, forming a contact plug such that the contact plug extends through the insulating layer and the passivation film while being partially positioned within the wafer, and forming a line layer on one end of the contact plug such that the line layer is electrically connected to the contact plug and the metal.

Embodiments relate to a stack package which includes a first semiconductor chip including a wafer, in which hydrogen ions are doped to a predetermined depth, a semiconductor device formed on the wafer, a metal electrically connected to the semiconductor device, a contact plug extending through an insulating layer arranged on the wafer, and a line layer electrically connected to the contact plug and the metal, a second semiconductor chip arranged over the first semiconductor chip, and a conductor arranged over the line layer such that the conductor is electrically connected to the line layer and the second semiconductor chip.

### DRAWINGS

FIGS. 1A to 1E are cross sectional views illustrating processes of a method for manufacturing a related semiconductor device.

FIG. 2 shows a cross-sectional image of a semiconductor device shown in FIG. 1E.

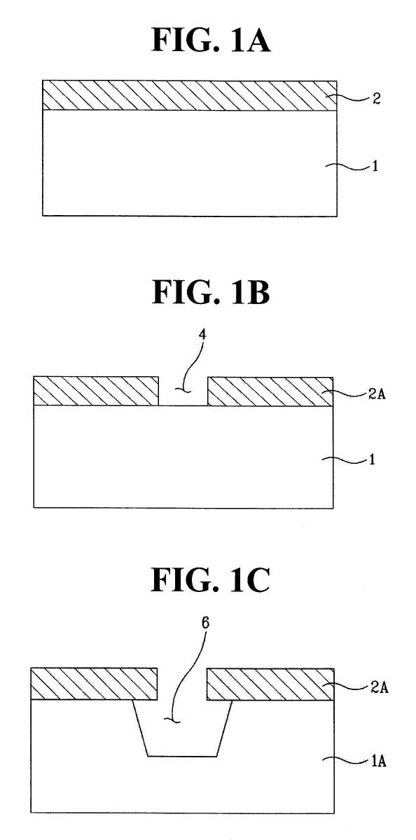

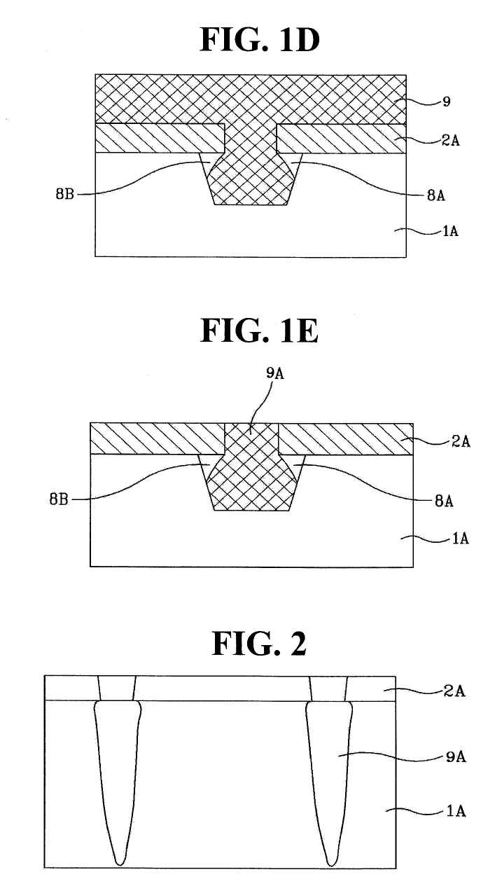

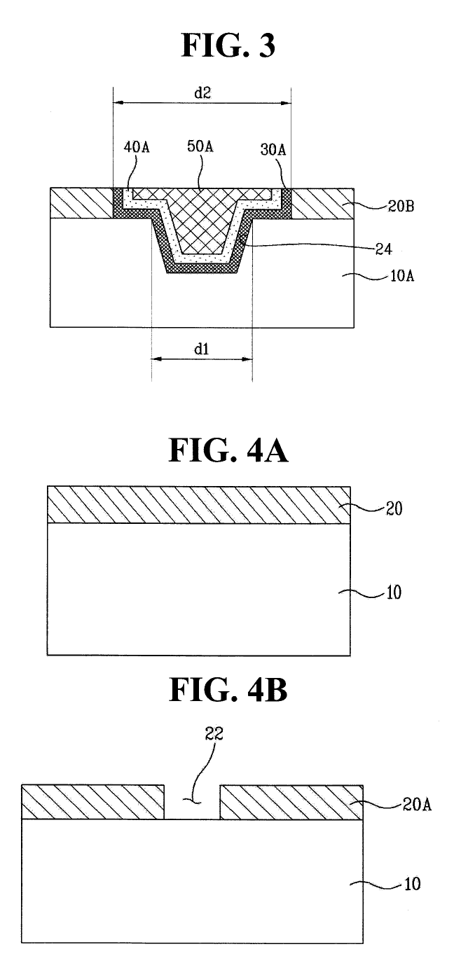

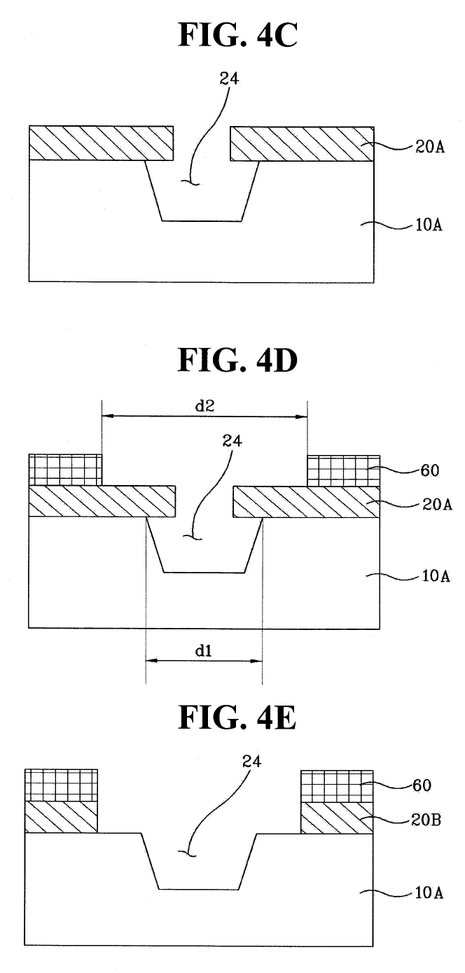

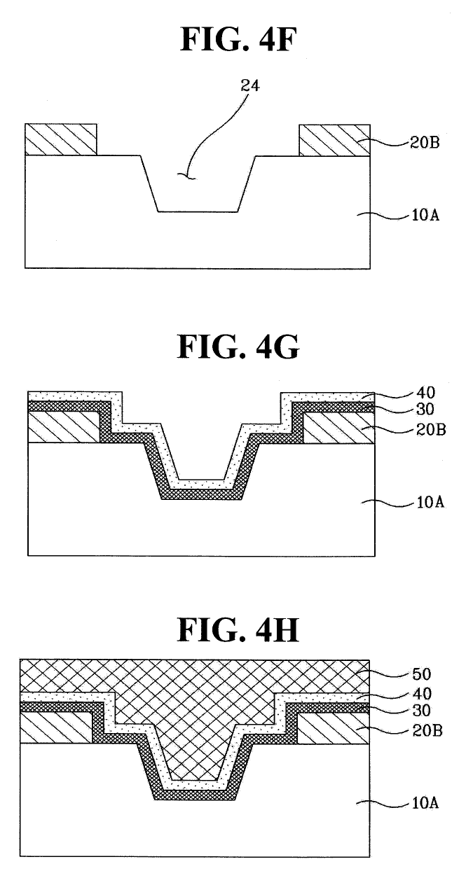

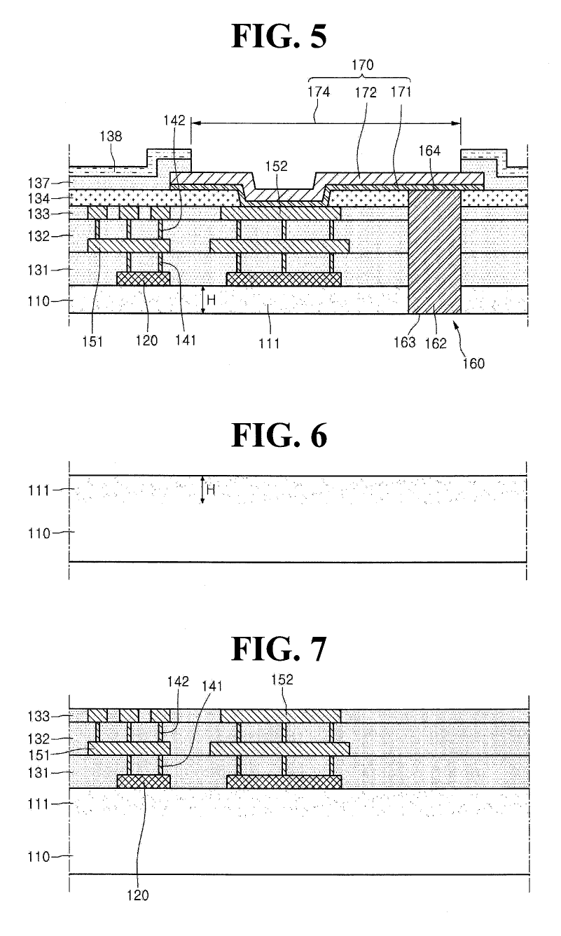

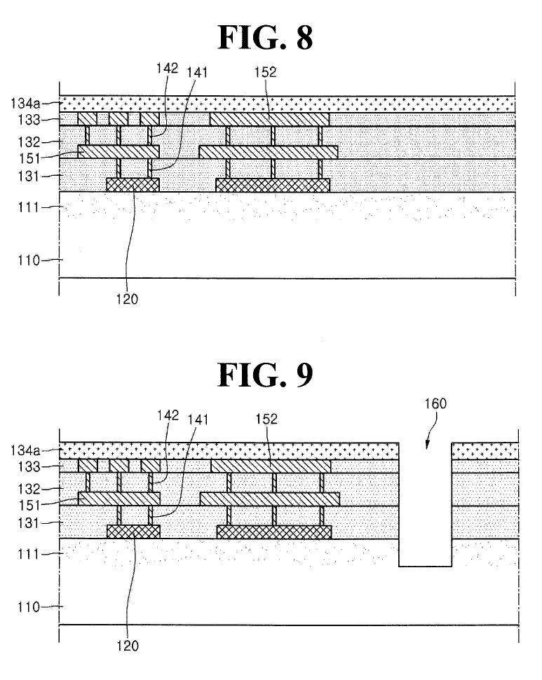

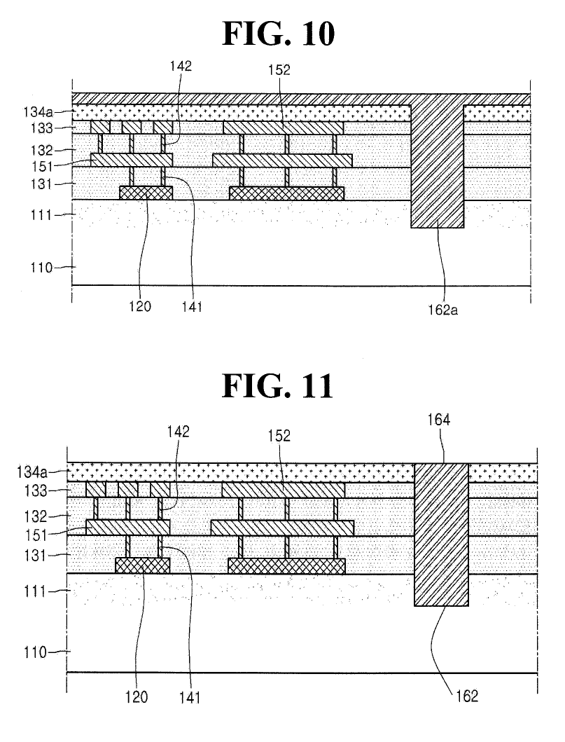

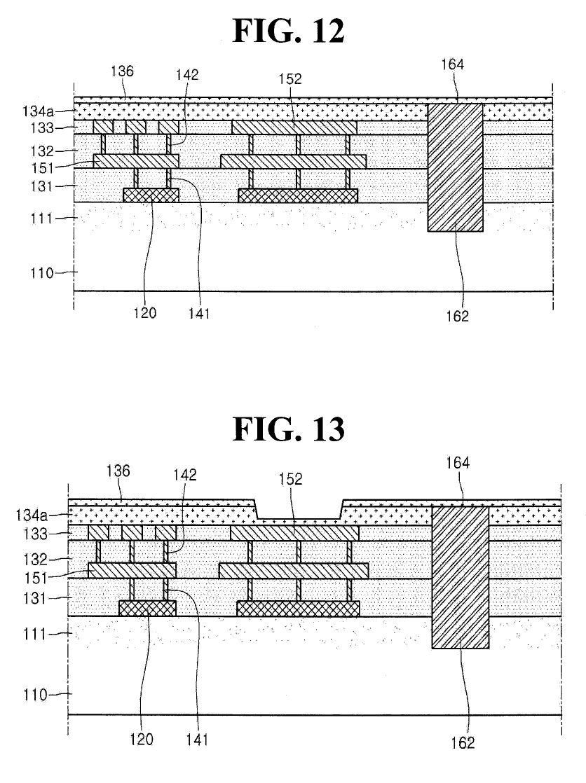

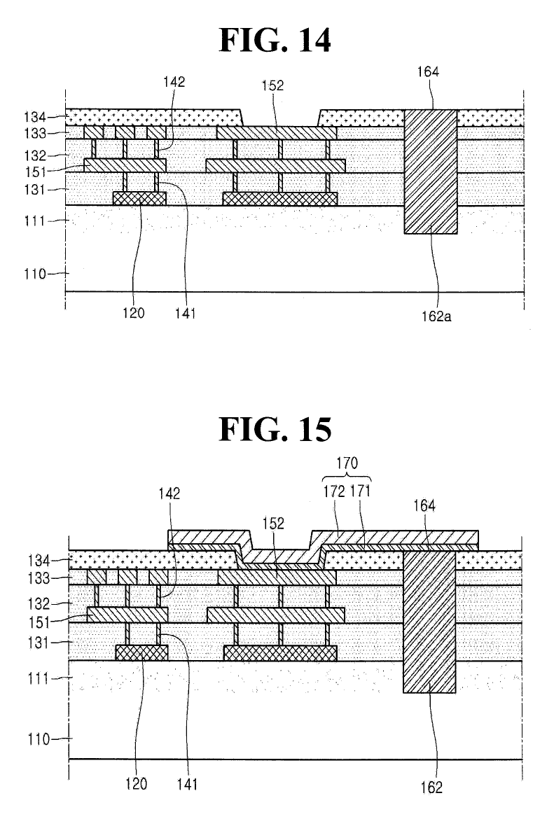

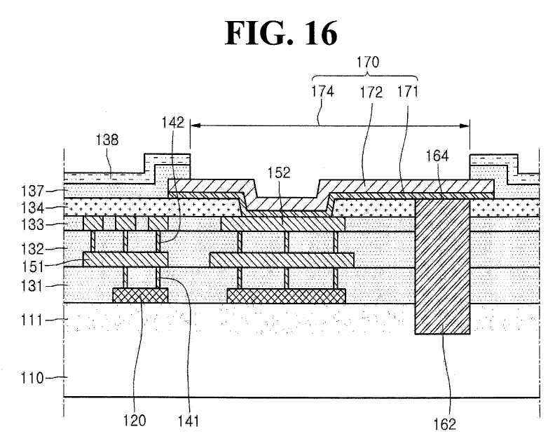

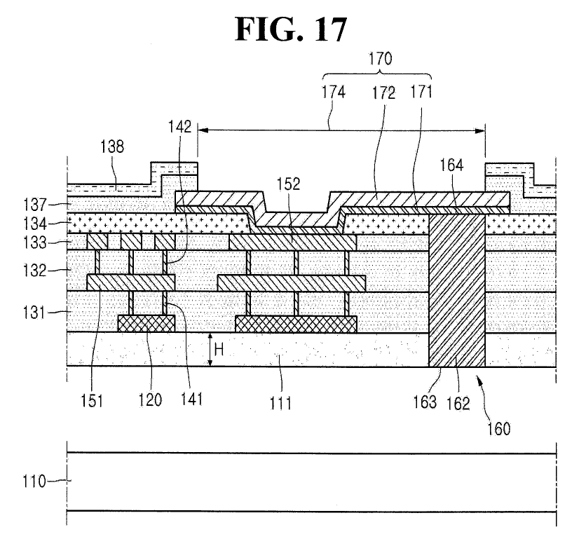

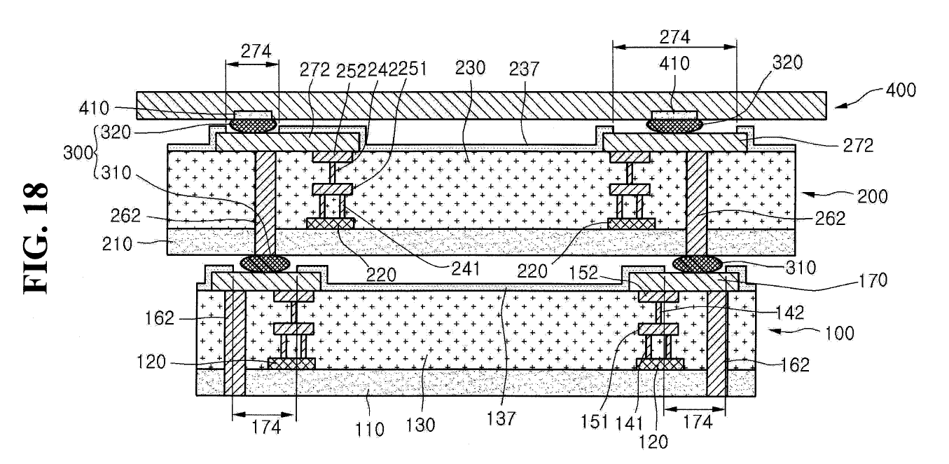

Example FIG. 3 is a sectional view of a semiconductor device according to embodiments.

Example FIGS. 4A to 4H are cross sectional views for explaining processes of a method for manufacturing the semiconductor device in accordance with embodiments.

Example FIG. 5 is a cross sectional view of a semiconductor chip according to embodiments.

Example FIGS. 6 to 17 are views for explaining a method for manufacturing the semiconductor chip in accordance with embodiments.

Example FIG. 18 is a view illustrating a semiconductor chip stack package using semiconductor chips in accordance with embodiments.

### DESCRIPTION

Example FIG. 3 is a sectional view of a semiconductor device according to embodiments.

Referring to example FIG. 3, a via hole 24 may be formed in a first material layer 10A. An etch mask 20B may be formed over the first material layer 10A, to expose a region d2 larger than a region d1 exposed through the via hole 24. As will be described later, the etch mask 20B may be formed by patterning a second material layer 20 having an etch selectivity different from that of the first material layer 10A.

A metal layer 50A may be formed over the first material layer 10A, to fill the via hole 24. An oxidation barrier film 30A may further be provided in the via hole 24. The oxidation barrier film 30A may be formed between the first material layer 10A and the metal layer 50A.

A barrier metal film 40A may also be formed between in the first material layer 10A and the metal layer 50A in the via hole 24. In this case, the oxidation barrier film 30A may be formed between the first material layer 10A and the barrier metal film 40A in the via hole 24. The barrier metal film 40A functions to prevent the metal material of the metal layer 50A from being diffused into the first material layer 10A.

In accordance with embodiments, the first material layer 10A and the second material layer 20 forming the etch mask 20B may have different etch selectivities. For example, the first material layer 10A may be a silicon layer, whereas the second material layer may be a back-end-of-the-line (BEOL) oxide film.

The metal layer 50A according to embodiments may be a via formed in accordance with a non-Bosch process, or a deep via formed through a silicon layer in a system-in-package (SIP). That is, the semiconductor device according to embodiments may be applied to a stack system integrated circuit (IC) based on a deep via technique.

Hereinafter, a method for manufacturing the above-described semiconductor device in accordance with embodiments will be described with reference to the accompanying drawings. Example FIGS. 4A to 4H are cross sectional views for explaining processes of a method for manufacturing the semiconductor device in accordance with embodiments.

Referring to example FIG. 4A, the first and second material layers 10 and 20, which have different etch selectivities, may be sequentially formed in a laminated fashion. That is, the second material layer 20 may be formed over the first material layer 10. As described above, the first material layer 10 may be a silicon layer, whereas the second material layer 20 may be a BEOL oxide film.

Thereafter, as shown in example FIG. 4B, the second material layer 20 may be patterned in accordance with a photo and etching process, thereby forming the etch mask 20A to expose a region 22 where the via hole 24 will be formed. Using the etch mask 20A, the first material layer 10 may then be etched, to form the via hole 24 in the first material layer 10A, as shown in example FIG. 4C.

Subsequently, a photo mask 60 may be formed over the etch mask 20A such that it exposes the region d2 larger than the region d1 exposed through the via hole 24, as shown in example FIG. 4D. In the illustrated embodiment, the photo mask 60 may be formed using a photoresist material. Of course, embodiments are not limited to the above case. The photo mask 60 may be formed using a material other than the photoresist material. Thereafter, the etch mask 20A may be etched using the photo mask 60, as shown in example FIG. 4E. The photo mask 60 may then be removed in accordance with an ashing process, as shown in example FIG. 4F.

After the removal of the photo mask 60, the oxidation barrier film 30 may be formed in the via hole 24, as shown in example FIG. 4G. The barrier metal film 40 may further be formed in the via hole 24. In this case, the oxidation barrier film 30 may be formed over the first material layer 10A in the via hole 24. The barrier metal film 40 may be formed over the oxidation barrier film 30. For example, the barrier metal film 40 may be formed by depositing TaN or Ta over the oxidation barrier film 30 in accordance with a physical vapor deposition (PVD) method.

Thereafter, a metal material 50 may be deposited over the barrier metal film 40, to fill the via hole 24, as shown in example FIG. 4H. For example, a copper seed layer may be formed over the barrier metal film 40. In this case, a copper layer 50 may be grown from the copper seed layer in accordance with an electroplating method, to sufficiently fill the via hole 24. Subsequently, the metal material 50 may be planarized until an upper surface of the etch mask 20A is exposed, in accordance with a chemical mechanical polishing (CMP) process, thereby forming the metal layer 50A, as shown in example FIG. 3.

Where the barrier metal film 40 is deposited in accordance with a PVD process, as mentioned above, a degradation in step coverage occurs. In embodiments, however, the etch mask 20A may be etched using the photo mask 60, to prevent generation of an undercut. Accordingly, the copper seed layer for the formation of the metal layer 50A can be easily deposited over the barrier metal film 40. Thus, an excellent conductive line, which has no void, may be formed in a copper plating process.

Hereinafter, a semiconductor chip according to embodiments will be described with reference to the accompanying drawings. Example FIG. 5 is a cross sectional view of a semiconductor chip according to embodiments.

Referring to example FIG. 5, the semiconductor chip may include a silicon wafer 110, a semiconductor device 120, a first insulating layer 131, a first via 141, a lower line 151, a second insulating layer 132, a second via 142, a third insulating layer 133, a top metal 152, a first passivation film 134, a via hole 160, a barrier metal, a contact plug 162, a line layer 170, a second passivation film 137, and a third passivation film 138.

In particular, the wafer 110 may have a thickness ranging from 2 to 5 μm. Predetermined impurity ions 111 may be doped (or implanted) in the wafer 110. For example, hydrogen (H₂) impurity ions 111 may be doped in the wafer 110. The hydrogen impurity ions 111 function to relieve the necessity for the wafer 110 to be deeply etched in a wafer etching process for forming the contact plug 162.

Also, where a cutting process such as a smart cutting process is carried out on the wafer after the formation of the semiconductor chip, it is possible to easily separate a doped wafer portion, where the hydrogen impurity ions 111 are doped, from an undoped wafer portion. In addition, even where a backgrinding process is carried out after the cutting of the wafer 110, it is possible to prevent a back crack phenomenon from occurring in the wafer in which the hydrogen impurity ions 111 are doped.

The doping depth of hydrogen impurity ions 111 may be selected, taking into consideration the thickness of the contact plug 162 located in the wafer 110. As described above, the hydrogen ions 111 may be doped to a thickness of 2 to 5 μm. The dose of hydrogen impurity ions may be 10¹³ to 10¹⁵ ions/cm³.

Meanwhile, the silicon wafer 110 may have a plate shape. The material used for the silicon wafer 110 may be, for example, single crystal silicon. The semiconductor device 120 may be formed on the silicon wafer 110. The semiconductor device 120 may be, for example, a double diffused metal oxide semiconductor (DMOS) transistor, a CMOS transistor, a bi-junction transistor, a diode, etc. The semiconductor device 120 may include a gate electrode, a source electrode, a drain electrode, a channel region, etc.

The first insulating layer 131 may cover the semiconductor device 120, to insulate the semiconductor device 120. The first via 141 may extend through the first insulating layer 131 such that it is electrically connected with the semiconductor device 120. The lower line 151 may be formed over the first insulating layer 131 such that it is electrically connected to the first via 141. That is, the semiconductor device 120 and lower line 151 may be electrically connected by the first via 141.

The second insulating layer 132 may cover the lower line 151, to insulate the lower line 151. The second via 142 may extend through the second insulating layer 132 such that it is electrically connected to the lower line 151. The top metal 152 may be formed over the second insulating layer 132 such that it is electrically connected to the second via 142. That is, the lower line 151 and top metal 152 may be electrically connected by the second via 142. The material usable for the first via 141, lower line 151, second via 142, and top metal 152 may be, for example, copper (Cu), tungsten (W), aluminum (Al), etc.

The third insulating layer 133 may be arranged over the second insulating layer 132. Through the third insulating layer 133, an upper surface of the top metal 152 may be exposed. The third insulating layer 133 may insulate side surfaces of the top metal 152.

The first passivation film 134 may cover the top metal 152. The first passivation film 134 may be provided with a first hole, through which the top metal 152 is partially exposed. The material used for the first passivation film 134 may be, for example, a nitride, etc. The first passivation film 134 may have a thickness of about 2,000 to 3,000 Å.

The via hole 160 may extend through the silicon wafer 110, first insulating layer 131, second insulating layer 132, third insulating layer 133, and first passivation film 134. The via hole 160 may have a diameter of about 10 μm to 30 μm.

A buffer film may be arranged over an upper surface of the first passivation film 134 and an inner surface of the via hole 160. The material used for the buffer film may be, for example, an oxide, etc. The buffer film may include the second hole through which the top metal 152 is partially exposed. The buffer film functions to prevent the material of the contact plug 162 from being diffused into the silicon wafer 110 or into the first to third insulating layers 131, 132, and 133.

The barrier metal may be formed in the via hole 160. In this case, the barrier metal functions to prevent the material of the contact plug 162 from being diffused into the silicon wafer 110 or into the first to third insulating layers 131, 132, and 133.

The contact plug 162 is arranged in the via hole 160. The material used for the contact plug 162 may be, for example, copper, copper alloy, tungsten, silver, etc. The contact plug 162 may have, for example, a pillar shape. The contact plug 162 may also have, for example, a cylindrical shape. The contact plug 162 has opposite ends 163 and 164. One of the opposite ends 163 and 164, namely, the end 164, may be covered by the line layer 170, whereas the other end, namely, the end 163, may be exposed.

The line layer 170 may include a first redistribution line metal film 171 and a second redistribution line metal film 172. The line layer 170 may be arranged over the first passivation film 134 such that it covers the end 164 of the contact plug 162. The line layer 170 also may cover the top metal 152 exposed through the first and second holes. The line layer 170 may be electrically connected with the contact plug 162 and top metal 152. The line layer 170 may include a pad region 174 in addition to the first and second line layers 171 and 172.

The first line layer 171 may cover the end 164 of the contact plug 162. The first line layer 171 also may cover the top metal 152 exposed through the first and second holes. The first line layer 171 may prevent a metal used to form the second line layer 172 which is later described, from being diffused into the top metal 152 and contact plug 162. The metal usable for the first line layer 171 may be, for example, titanium (Ti), titanium nitride (TiN), titanium silicon nitride (TiSiN), tantalum (Ta), tantalum nitride (TaN), tantalum silicon nitride (TaSiN), etc.

The second line layer 172 may be formed over the first line layer 171 in a laminated fashion. The material usable for the second line layer 172 may be, for example, aluminum, aluminum alloy, etc.

The pad region 174 may be exposed through third and fourth holes, which will be described later. The pad region 174 may be electrically connected to another semiconductor chip or a printed circuit board (PCB) via a conductor.

The second passivation film 137 may be arranged over the first passivation film 134. The second passivation film 137 may cover the line layer 170. Of course, a first oxide film may be further formed, as a buffer film, between the first passivation film 134 and the second passivation film 137. The second passivation film 137 protects the line layer 170. The second passivation film 137 may be provided with the third hole, through which the pad region 174 is exposed. The material usable for the second passivation film 137 may be, for example, an oxide, etc.

The third passivation film 138 may be arranged over the second passivation film 137. The third passivation film 138 protects the line layer 170. The third passivation film 138 may be provided with the fourth hole, through which the pad region 174 may be exposed. The material usable for the third passivation film 138 may be, for example, a nitride, etc.

A secondary semiconductor chip may be arranged over the semiconductor chip according to embodiments. The secondary semiconductor chip may be electrically connected to the first semiconductor chip via the conductor arranged over the pad region 174. In this case, the pad region 174 may be formed at a desired position over an upper surface of the first semiconductor chip.

By virtue of hydrogen ions doped in only one portion of the wafer 110 to form the contact plug 162 extending through the wafer 110, it is possible to easily separate the doped portion of the wafer 110 from an undoped portion in a cutting process. Also, no crack is generated at the wafer 110 even when the back surface of the wafer 110 is ground after the separation.

Hereinafter, a method for manufacturing the semiconductor chip in accordance with embodiments will be described with reference to the accompanying drawings. Example FIGS. 6 to 17 are views for explaining a method for manufacturing the semiconductor chip in accordance with embodiments.

First, as shown in example FIG. 6, the silicon wafer 110 may be prepared, in order to make the semiconductor chip, which includes semiconductor devices and lines. A process for doping impurity ions into the silicon wafer 110 may then be carried out.

The ion doping process may be carried out at a dose of hydrogen ions ranging from 10¹³ to 10¹⁵ ions/cm³ and high doping energy of 400 KeV to 1,000 KeV. The ion doping process may be carried out to dope the hydrogen ions to a depth of 2 μm to 5 μm from the surface of the wafer 110. The doping depth H of impurity ions determines a wafer separation position in a subsequent process, as described with reference to example FIG. 5.

Thereafter, the semiconductor devices 120 may be formed on the silicon wafer 110, in which impurity ions have been doped to a predetermined depth, as shown in example FIG. 7. The first insulating layer 131 may be formed to cover the semiconductor devices 120.

The first via 141 may be subsequently formed such that it extends through the first insulating layer 131 while being electrically connected to the semiconductor devices 120. The lower line 151 may then be formed over the first insulating layer 131 such that it is electrically connected to the first via 141.

Thereafter, the second insulating layer 132 may be formed to cover the lower line 151. The second via 142 may be subsequently formed such that it extends through the second insulating layer 132 while being electrically connected to the lower line 151. The top metal 152 may then be formed over the second insulating layer 132 such that it is electrically connected to the second via 142.

Thereafter, the third insulating layer 133 may be formed to cover the top metal 152. The top metal 152 and third insulating layer 133 may then be planarized in accordance with a chemical mechanical polishing (CMP) process such that an upper surface of the top metal 152 is exposed. The material usable for the first via 141, lower line 151, second via 142, and top metal 152 may be, for example, copper (Cu), tungsten (W), etc.

Following the CMP process, a first nitride film 134a may be formed to cover the top metal 152 and third insulating layer 133, as shown in example FIG. 8. The material usable for the first nitride film 134a may be, for example, a nitride, etc. The first nitride film 134a may be formed in accordance with a chemical vapor deposition (CVD) process. The first nitride film 134a may have a thickness of about 2,000 Å to 3,000 Å.

As shown in example FIG. 9, after the formation of the first nitride film 134a, the via hole 160 may be formed to extend through a portion of the silicon wafer 110, first insulating layer 131, second insulating layer 132, third insulating layer 133, and first nitride film 134a.

In particular, in an etching process for forming the via hole 160, it may be unnecessary to etch the wafer 110 to a deep depth by virtue of a high etch selectivity. That is, the via hole 160 may be formed to a depth of the impurity ions doped in the wafer 110.

In other words, the wafer 110 may be etched to the depth of the impurity ions doped in the wafer 110. As a result, the contact plug, which is filled to be formed in the via hole 160 in accordance with a gap filling process, can extend through the ion doped region of the wafer 110. This will be described later.

After the formation of the via hole 160, the first oxide film may be formed as a buffer film, as shown in example FIG. 10. The first oxide film may be formed to a predetermined thickness over an upper surface of the first nitride film 134a while filling the via hole 160. The material used for the first oxide film may be, for example, a silicon oxide (SiOₓ).

After the formation of the first oxide film, the barrier metal film may be formed over the first oxide film. The material usable for the barrier metal film may be, for example, titanium (Ti), titanium nitride (TiN), titanium silicon nitride (TiSiN), tantalum (Ta), tantalum nitride (TaN), tantalum silicon nitride (TaSiN), etc. The thickness of the barrier metal film may be about 1,000 Å to 3,000 Å.

A metal 162a may be filled in the via hole 160 in accordance with a gap filling process, to form a contact plug. The material used for the metal 162 to form a contact plug may be, for example, copper, copper alloy, tungsten, silver, etc.

After the deposition of the metal 162a according to the gap filling process for the formation of a contact plug, a portion of the first oxide film formed over the first nitride film 134a and the metal 162a formed over the first nitride film 134a may be removed in accordance with a CMP process, as shown in example FIG. 11. In this case, the first oxide film may be planarized. Thus, the contact plug 162 may be formed.

The second nitride film 136 may then be formed over the first nitride film 134a and contact plug 162, as shown in example FIG. 12. The material of the second nitride film 136 may be identical to the material of the first nitride film 134a. The second nitride film 136 prevents the contact plug 162 from being oxidized.

After the formation of the second nitride film 136, a photoresist pattern may be formed over the second nitride film 136, as shown in example FIG. 13. The photoresist pattern may be formed in accordance with a photo process including a development process and an exposure process. A portion of the second nitride film 136 corresponding to the top metal 152 may be exposed through the photoresist pattern.

Using the photoresist pattern as the etch mask, a portion of the first nitride film 134a, the first oxide film, and the second nitride film 136 may be etched. At this time, the portion of the second nitride film 136 corresponding to the top metal 152 may also be removed. In the process of etching the second nitride film 136, the first nitride film 134a may be partially left to a predetermined thickness over the top material 152.

The second nitride film 136 and the first nitride film 134a left to a certain thickness over the top metal 152 may be removed in accordance with a blanket etching process, as shown in example FIG. 14. As a result, the top metal 152 may be partially exposed through an opening formed through the first nitride film 134a. In accordance with the removal of the second nitride film 136 and the portion of the first nitride film 134a, the first passivation film 134, which has the opening to expose the top metal 152, is completed. Where the first oxide film is formed over the first passivation film 134, the opening to expose the top metal 152 may also extend through the first oxide film. That is, the first nitride film 134, which has the opening to partially expose the top metal 152, may be referred to as the first passivation film 134. The first oxide film, which may be formed over the first passivation film 134 while having the opening, may be referred to as a buffer film.

After the partial exposure of the top metal 152 through the first passivation film 134, the first redistribution line metal film 171 may be formed to cover a portion of the top metal 152 and the end 164 of the contact plug 162, as shown in example FIG. 15. The material used for the first redistribution line metal film 171 may be, for example, titanium, titanium nitride, titanium silicon nitride, tantalum, tantalum nitride, tantalum silicon nitride, etc.

Thereafter, the second redistribution line metal film 172 may be formed over the first redistribution line metal film 171. The material usable for the second redistribution line metal film 172 may be, for example, aluminum, aluminum alloy, etc. The first and second redistribution line metal films 171 and 172 may then be patterned to form the line layer 170 covering the top metal 152 and contact plug 162. The line layer 170 may be electrically connected to the top metal 152 and contact plug 162.

After the formation of the line layer 170 over the top metal 152 and contact plug 162, a second oxide film and a third nitride film may be sequentially formed over the line layer 170, as shown in example FIG. 16. The material usable for the second oxide film may be, for example, undoped silicon glass (USG), tetraethyl orthosilicate (TEOS) oxide, etc. The second oxide film may have a thickness of about 10,000 Å to 15,000 Å. The material usable for the third nitride film may be, for example, a silicon nitride (SiNₓ), etc. The third nitride film may have a thickness of about 10,000 Å to 13,000 Å. The second oxide film and third nitride film may be patterned in accordance with a mask process, to form the second passivation film 137 and third passivation film 138, through which the line layer 170 is partially exposed.

In openings formed through the second and third passivation films 137 and 138, a conductor for electrical connection with an external configuration may be formed. That is, a conductor formation region is defined as the pad region 174 by the second and third passivation films 137 and 138. In other words, when the line layer 170 is partially exposed in accordance with patterning of the second and third passivation films 137 and 138, the upper region of the exposed line layer 170 may become the conductor formation region as the pad region 174.

As shown in example FIG. 17, after the forming of the conductor formation region over the line layer 170 as the pad region 174, a process for partially cutting a lower portion of the silicon wafer 110 may be carried out. In this case, as SIP wafer, a portion of the silicon wafer 110 doped with hydrogen ions and an undoped portion arranged beneath the doped portion may be separated from each other in accordance with a cleaving process such as smart cutting process. In this case, the thickness H of the remaining silicon wafer 110 may be about 2 μm to 5 μm.

Hereinafter, a semiconductor chip stack package using the semiconductor chip according to embodiments will be described. Example FIG. 18 is a view illustrating a semiconductor chip stack package using semiconductor chips in accordance with embodiments.

For first and second semiconductor chips included in the semiconductor chip stack package, a semiconductor chip according to the above-described embodiments may be used. The semiconductor chip stack package may include a first semiconductor chip 100, a second semiconductor chip 200, a conductor 300, and a circuit board 400. The first semiconductor chip 100 may include a first silicon wafer 110, a first semiconductor device 120, an insulating layer 130, a first top metal 152, a first contact plug 162, a first line layer 170, and a first line layer passivation film 137.

The insulating layer 130 of the first semiconductor chip 100 may be formed to cover the first semiconductor device 120. The insulating layer 130 may include a plurality of laminated insulating layers. The first top metal 152 may be formed over the insulating layer 130. The first top metal 152 may be electrically connected with the first semiconductor device 120 through vias 141 and 142 extending through the insulating layer 130 and lines 151 each arranged between the adjacent insulating layers of the insulating layer 130.

The first contact plug 162 may extend through the insulating layer 130 and first silicon wafer 110. One end of the first contact plug 162 may be exposed. The first line layer 170 may cover an end of the first contact plug 162 opposite to the exposed end. The first line layer 170 may also completely or partially cover the first top metal 152. The first line layer 170 may be electrically connected to the first contact plug 162 and first top metal 152. The first line layer 170 may include a first pad region 174, which is externally exposed. The first line layer passivation film 137 may cover the first line layer 170. The first line layer passivation film 137 may have a hole, through which the first pad region 174 is exposed.

The second semiconductor chip 200 is arranged over the first semiconductor chip 100. The second semiconductor chip 200 may include a second silicon wafer 210, a second semiconductor device 220, an insulating layer 230, a second top metal 252, a second contact plug 262, a second line layer 272, and a second line layer passivation film 237. The second semiconductor device 220 may be formed on the second silicon wafer 210. The insulating layer 230 may be formed to cover the second semiconductor device 220. The insulating layer 230 may include a plurality of laminated insulating layers.

The second top metal 252 may be formed over the insulating layer 230. The second top metal 252 may be electrically connected with the second semiconductor device 220 through vias 241 and 242 extending through the insulating layer 230 and lines 251 each arranged between the adjacent insulating layers of the insulating layer 230. The second contact plug 262 may extend through the insulating layer 230 and second silicon wafer 210. One end of the second contact plug 262 may be in contact and electrically connected with the conductor 300.

The second line layer 272 may cover an end of the second contact plug 262 opposite to the end of the second contact plug 262 electrically connected to the conductor 300. The second line layer 272 may also partially cover the second top metal 252. The second line layer 272 may be electrically connected to the second contact plug 262 and second top metal 252. The second line layer 272 may include a second pad region 274, which is externally exposed.

The second line layer passivation film 237 may cover the second line layer 272. The second line layer passivation film 237 may have a hole, through which the second pad region 274 is exposed.

The conductor 300 may include a first conductor 310 and a second conductor 320. The first conductor 310 may be interposed between the first semiconductor chip 100 and the second semiconductor chip 200. The first conductor 310 may be in contact and electrically connected with the first and second pad regions 174 and 274. That is, the first conductor 310 may electrically connect the first and second semiconductor chips 100 and 200.

The second conductor 320 may be interposed between the second semiconductor chip 200 and the circuit board 400. The second conductor 320 may be in contact with the first pad region 174 and a third pad region 410 so that they are electrically connected. That is, the second conductor 320 may electrically connect the first semiconductor chip 100 to the circuit board 400, which will be described later. The conductor 300 may be, for example, a silver (Ag) solder paste.

The circuit board 400 may be arranged over the second semiconductor chip 200. The circuit board 400 may include printed lines formed therein. The third pad region 410 may also be included in the circuit board 400. The third pad region 410 may be electrically connected to the printed lines while being externally exposed. The circuit board 400 may be arranged over the second semiconductor chip 200 such that the second conductor 320 and third pad region 410 are in contact with each other.

The first pad region 174 may be formed at a desired position. Accordingly, the second contact plug 262 corresponding to the first pad region 174 may also be formed at a desired position. Thus, the semiconductor chip stack package may be designed irrespective of the positions of the first semiconductor device 120, first top metal 152, and first contact plug 162.

In the semiconductor device and manufacturing method thereof according to embodiments, a metal layer is formed using a damascene process. Accordingly, it is possible to prevent generation of a side wall undercut in a deep via etching process, and thus to easily achieve subsequent processes for forming an oxide barrier film, a barrier metal film, and a metal layer.

In the semiconductor chip and manufacturing method thereof according to embodiments, and the stack package according to embodiments, it is possible to adjust the vertical length of the contact plug extending into the silicon wafer. Also, it is possible to cut the back surface of the wafer even in a cleaving process to separate the wafer into portions.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
sequentially forming first and second material layers having different etch selectivities in a laminated fashion;
patterning the second material layer, to form an etch mask;
etching the first material layer using the etch mask, to form a via hole in the first material layer;
forming a photo mask over the etch mask such that a region larger than the via hole is exposed through the photo mask;
etching the etch mask using the photo mask;
removing the photo mask; and
forming a metal material over the first material layer, to fill the via hole.

2. The method of claim 1, including:
forming an oxidation barrier film in the via hole after the removal of the photo mask.

3. The method of claim 1, including:
forming a barrier metal film in the via hole.

4. The method according to claim 1, wherein the first material layer is a silicon layer.

5. The method of claim 4, wherein the second material layer is an oxide film.

6. The method of claim 1, including:
planarizing the metal material until the etch mask is exposed, to form a metal layer.

7. An apparatus comprising:
a via hole formed in a first material layer;
an etch mask formed over the first material layer in accordance with patterning of a second material layer having an etch selectivity different from an etch selectivity of the first material layer, the etch mask exposing a region larger than the via hole; and
a metal layer formed over the first material layer such that the metal layer fills the via hole.

8. The apparatus of claim 7, including:
an oxidation barrier film formed in the via hole between the first material layer and the metal layer.

9. The apparatus of claim 7, including:
a barrier metal film formed in the via hole between the first material layer and the metal layer.

10. The apparatus of claim 9, including:
an oxidation barrier film formed in the via hole between the first material layer and the barrier metal film.

11. An apparatus comprising:
a wafer doped with impurity ions;
a semiconductor device formed on the wafer;
a metal electrically connected to the semiconductor device;
a contact plug extending through an insulating layer formed on the wafer such that the contact plug is partially positioned within the wafer; and
a line layer formed at one end of the contact plug, and electrically connected to the contact plug and the metal.

12. The apparatus of claim 11, wherein the impurity ions doped in the wafer are hydrogen ions.

13. The apparatus of claim 11, wherein the contact plug extends through an ion doped region of the wafer where the impurity ions are doped.

14. The apparatus of claim 11, including:
a barrier metal and a buffer film, which are formed between the wafer and the contact plug.

15. A method comprising:
doping impurity ions in a wafer to a predetermined depth;
forming, on the wafer, a semiconductor device, an insulating layer to cover the semiconductor device, and a metal to be electrically connected to the semiconductor device;
forming a passivation film to cover the metal;
forming a contact plug such that the contact plug extends through the insulating layer and the passivation film while being partially positioned within the wafer; and
forming a line layer over one end of the contact plug such that the line layer is electrically connected to the contact plug and the metal.

16. The method of claim 15, wherein the impurity ions doped in the wafer are hydrogen ions.

17. The method of claim 16, wherein the hydrogen ions are doped to a depth of 2 μm to 5 μm from a surface of the wafer.

18. The method of claim 15, wherein the contact plug extends through an ion doped region of the wafer where the impurity ions are doped.

19. The method of claim 18, including:
cutting the wafer after the formation of the line layer,
wherein the cutting of the wafer is carried out to remove a portion of the wafer arranged beneath the ion doped region.

20. An apparatus comprising:
a first semiconductor chip including a wafer, in which hydrogen ions are doped to a predetermined depth, a semiconductor device formed on the wafer, a metal electrically connected to the semiconductor device, a contact plug extending through an insulating layer arranged on the wafer, and a line layer electrically connected to the contact plug and the metal;
a second semiconductor chip arranged over the first semiconductor chip; and
a conductor arranged over the line layer such that the conductor is electrically connected to the line layer and the second semiconductor chip.
